(19) United States
(12) Patent Application Publication
(10) Pub. No.: US 2009/0237070 A1
(43) Pub. Date: Sep. 24, 2009

(54) METHOD OF INSTANTANEOUSLY DETERMINING OR ESTIMATING THE FREQUENCY OR AMPLITUDE OF AN INPUT SIGNAL

(76) Inventor: Paul Le Roux Herselman, Pretoria (ZA)

Correspondence Address: STRAUB & POKOTYLO, 788 Shrewsbury Avenue, TINTON FALLS, NJ, 07724, US

(21) Appl. No.: 12/162,593

(22) PCT Filed: Jan. 24, 2007
(86) PCT No.: PCT/IB2007/050238

§ 371 Date: Jul. 29, 2008

(30) Foreign Application Priority Data
Feb. 1, 2006 (ZA) 2006/00946

(51) Int. Cl. G01R 23/02

(52) U.S. Cl. 324/76.39; 324/76.44

(57) ABSTRACT

A method of instantaneously determining or estimating the frequency of an input signal includes mixing a digitally sampled and quantized input signal (12) by a time shifted replica of the input signal (12), where the time shift equals an integer multiple of a sampling period of the input signal (12), thereby producing a mixed signal. The mixed signal is filtered with a low-pass filter producing a filtered signal, which is used to obtain an estimate of the frequency of the input signal. The invention extends to an apparatus (8) for implementing the method in accordance with the invention. The invention also extends to a method of determining or estimating the amplitude of an input signal (12).

THIS INVENTION relates to a method of instantaneously determining or estimating the frequency of an input signal, and to a method of determining or estimating the amplitude of an input signal. The invention also extends to an apparatus for measuring the instantaneous frequency of an input signal.

According to a first aspect of the invention there is provided a method of instantaneously determining or estimating the frequency of an input signal, the method including:

mixing a digitally sampled and quantized input signal by a time shifted replica of the input signal, where the time shift equals an integer multiple of a sampling period of the input signal, thereby producing a mixed signal;

filtering the mixed signal with a low-pass filter producing a filtered signal; and

using the filtered signal to obtain an estimate of the frequency of the input signal.

The method may include the prior steps of:

sampling and quantising an input signal thereby to generate a digitally sampled and quantised input signal; and

shifting the digitally sampled and quantised input signal by an integer multiple of the sampling period of the input signal thereby to generate a time shifted replica of the input signal.

Typically, the method includes digitally sampling and quantizing the input signal at a constant sampling period, e.g. by way of an analog to digital converter (ADC).

Preferably, the time shift equals an odd integer multiple of the sampling period. Most preferably, the time shift equals the sampling period, i.e. the odd integer=1.

The filter may filter out second and any higher order harmonics of the mixed signal, so that the filtered signal is a constant. The low-pass filter may be a digital filter, such as a finite impulse response (FIR) filter.

Using the filtered signal to obtain an estimate of the frequency of the input signal may include using the filtered signal as a digital input to a digital frequency estimator, the digital frequency estimator being operable digitally to output an estimated frequency of the input signal based on the received filtered signal. The digital frequency estimator may include an inverse cosine estimator. The inverse cosine estimator may include a digital frequency look-up table.

The method may include obtaining an estimate of the square of the amplitude of the input signal, dividing the filtered signal with the estimate of the square of the amplitude of the input signal thereby producing a quotient signal, and using the quotient signal to obtain an estimate of the frequency of the input signal. It will be appreciated that the estimate of the frequency obtained in this fashion may be independent of the amplitude of the input signal.

The estimate of the square of the amplitude of the input signal may be obtained in the form of a digital word. The filtered signal may therefore be digitally divided by the estimate of the square of the amplitude of the input signal.

Obtaining the estimate of the square of the amplitude of the input signal may include:

mixing the sampled input signal with a duplicate of the sampled input signal to provide the square of the sampled input signal; and

filtering the square of the sampled input signal with a low-pass filter producing a filtered square of the sampled input signal, which is used as the estimate of the square of the amplitude of the input signal.

It will be noted that the same low-pass filter used to filter the mixed signal, as above described, may be used to filter the square of the sampled input signal.

The low-pass filter may filter out second and any higher order harmonics of the square of the sampled input signal, so that the filtered signal is a constant. The low-pass filter may be a digital filter, such as a finite impulse response (FIR) filter.

The method may be implemented on a programmable processing unit. The method may therefore include timesharing the processing unit such that on one clock cycle of the processing unit the filtered square of the sampled input signal is obtained and on an alternate clock cycle of the processing unit the filtered signal is obtained. The processing unit may be a field programmable gate array (FPGA), or the like.

The method may be implemented on a digital DRFM (digital radio frequency memory) module (DDM).

According to a second aspect of the invention there is provided an apparatus for measuring the instantaneous frequency of an input signal, the apparatus including:

a digital mixer operable digitally to mix a digitally sampled and quantized input signal by a sample shifted replica of the input signal, where the sample shift is an integer sample shift, thereby producing a mixed signal;

a digital low-pass filter operable to filter the mixed signal thereby producing a filtered signal; and

a digital frequency estimator operable to receive the filtered signal and output an estimate of the radian normalized frequency of the input signal or an estimate that is directly related thereto, based on the received filtered signal.

Preferably, the sample shift is a one sample delay.

The apparatus may include a programmable processing unit. The programmed processing unit may be programmed to include or define the digital mixer, the digital filter, and the digital frequency estimator. It will be understood that when referring to the programmable processing unit, “electronically connected” components will be understood to mean those components programmed into the processing unit which are conceptually connected to various other components programmed into the programmable processing unit.

The apparatus may further include:

a plurality of multiplier-filter elements programmed into the processing unit, the multiplier filter elements being operable digitally to mix the digitally sampled and quantised input signal by a sample delayed replica thereof, thereby producing the mixed signal, and also operable to multiply the mixed signal by finite impulse response (FIR) filter coefficients, thereby producing multiplier-filter outputs; and

an adder programmed into the processing unit, the adder being operable digitally to add the multiplier-filter outputs together, thereby producing an adder output which is the filtered signal, such that the digital mixer and the digital low-pass filter is implemented by way of the multiplier-filter elements and the adder. In other words, the digital mixer and the digital filter may be realised, in use, by way of the multiplier-filter elements and the adder.

The apparatus may also include:

an analog to digital converter (ADC) operable to sample and quantize an input signal thereby to generate a digitally sampled and quantized input signal; and

at least one de-multiplexer operable digitally to receive the sampled and quantized input signal from the ADC and digitally transfer the sampled and quantized input signal to an input bus of the programmable processing unit with a wider bus width and a lower data rate.

The digital frequency estimator may include an inverse cosine estimator. The inverse cosine estimator may include a frequency look-up table operable to receive the filtered signal and output an estimate of the radian normalized frequency of the input signal or an estimate that is directly related thereto, based on the received filtered signal.

Each multiplier-filter element of the programmable processing unit may include:

at least two multiplier-filter two-port multiplexers, both electronically connected to receive samples of the input signal from the input bus of the processing unit, the at least two multiplier-filter two-port multiplexers each defining output means operable to output a sample replica and a sample delayed replica of the input signal, or to output two sample replicas of the input signal, or to output two sample replicas of the input signal that are delayed by one or more programmable processing unit clock cycle(s);

a parallel processing multiplier operable digitally to multiply together the samples received from the output means of the multiplier-filter multiplexers, thereby to produce a mixed product; and

a finite impulse response (FIR) filter multiplier operable digitally to multiply the mixed product by a FIR filter coefficient, the FIR filter coefficients being low-pass filter coefficients.

It will be understood that the outputting of two sample replicas that are delayed by one or more processing unit clock cycle(s) by the output means of the multiplier-filter two-port multiplexers aligns the amplitude estimation with the frequency estimation, in accordance with the invention.

The apparatus may include a switch to switch the multiplier-filter multiplexers of the multiplier-filter element to output a sample and a sample delayed replica thereof on an m^{th} clock cycle, and to output two sample replicas or two samples that are delayed by one or more programmable processing unit clock cycle(s) on an (m+1)^{th} (alternate) clock cycle, such that the adder output is the filtered signal (sample delayed) on the m^{th} clock cycle and the adder output is an estimate of the square of the amplitude of the input signal on the (m+1)^{th} clock cycle. Alternatively, or in addition, the switch may be a toggle unit programmed into the programmable processing unit.

The programmable processing unit may also be programmed to include:

at least one amplitude de-multiplexer and a frequency de-multiplexer, both electronically connected to receive the adder output; and

an output multiplier operable to multiply together an input received from the amplitude de-multiplexer via an inverse amplitude look-up table, and also an input received from the frequency de-multiplexer, thereby to produce an output which is used as an input to the frequency look-up table which outputs an amplitude independent estimation of the normalized radian frequency of an input signal or an estimate that is directly related thereto.

The programmable processing unit may include cycle delay units electronically connected between the frequency de-multiplexer and the multiplier, operable to remove any cycle delay mismatch between the filtered signal and the inverse amplitude from the inverse amplitude look-up table at the input to the output multiplier.

The programmable processing unit may be a field programmable gate array (FPGA), or the like.

In a preferred embodiment of the invention, the apparatus may be a digital DRFM (digital radio frequency memory) module (DDM).

According to a third aspect of the invention there is provided a method of determining or estimating the amplitude of an input signal, the method including:

mixing a digitally sampled and quantized input signal with a duplicate of the sampled input signal to provide a square of the sampled input signal;

filtering the square of the sampled input signal with a low-pass filter producing a filtered square of the sampled input signal; and

using the filtered square of the sampled input signal to determine or estimate the amplitude of the input signal.

The low-pass filter may filter out second and any higher order harmonics of the square of the sampled input signal, such that the filtered signal is a constant. The filter may be a digital filter, such as a FIR (finite impulse response) filter.

The method may be implemented on a programmable processing unit such as a FPGA, or the like.

Preferably, the method may be implemented on a digital DRFM (digital radio frequency memory) module (DDM).

The invention will now be described by way of example with reference to the accompanying diagrammatic drawings.

In the drawings,

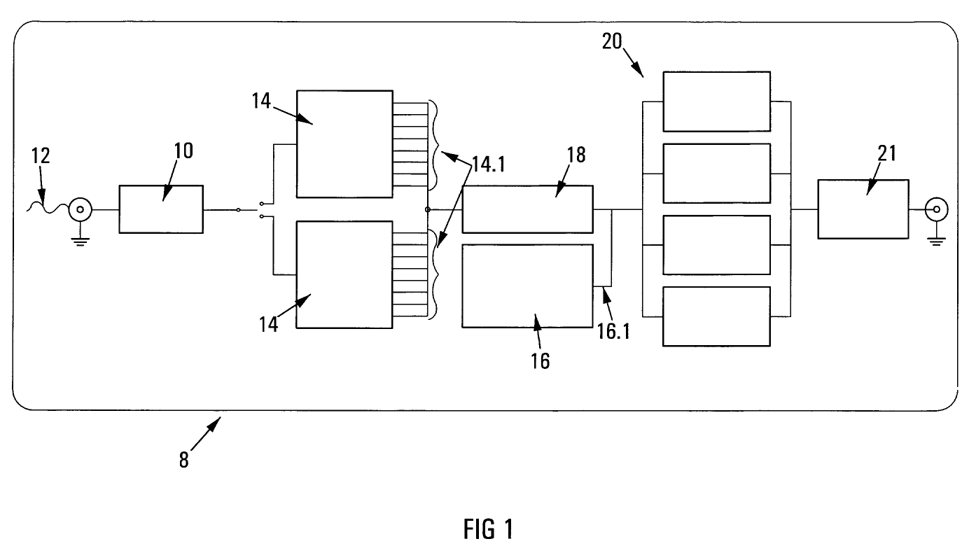

FIG. 1 shows a basic block diagram of an apparatus in accordance with the invention for measuring an instantaneous frequency of a signal;

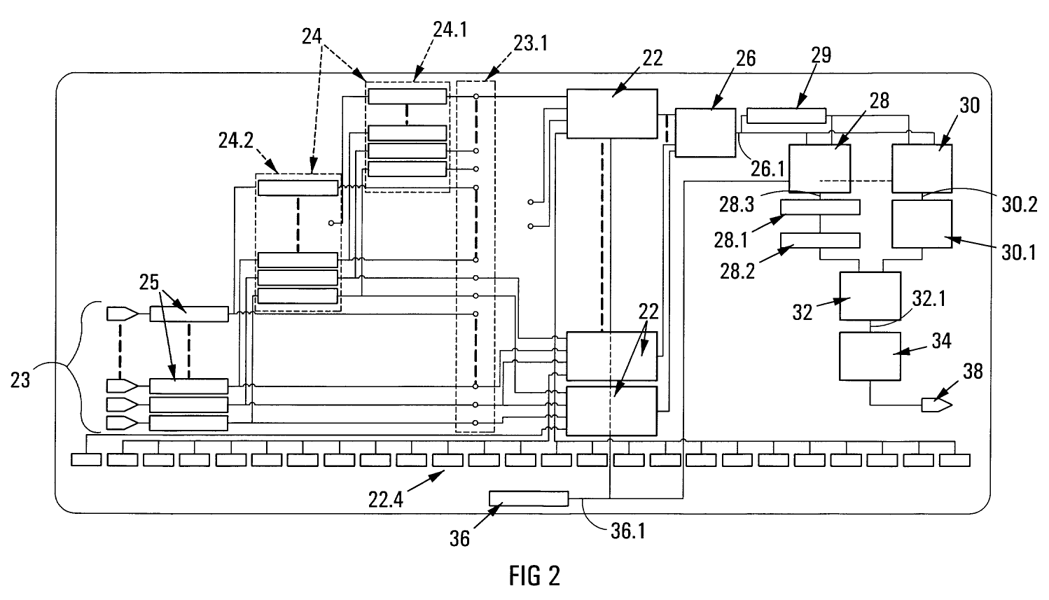

FIG. 2 shows, in part, a detailed schematic block diagram of the implementation of signal processing associated with an instantaneous frequency measurement method in accordance with the invention, on an FPGA;

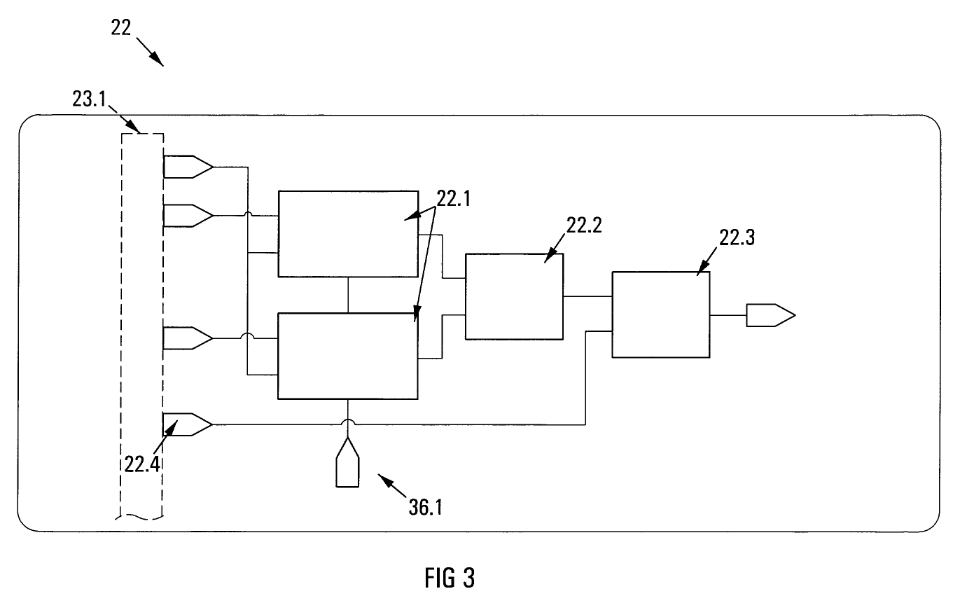

FIG. 3 shows a schematic diagram of a multiplier-filter element;

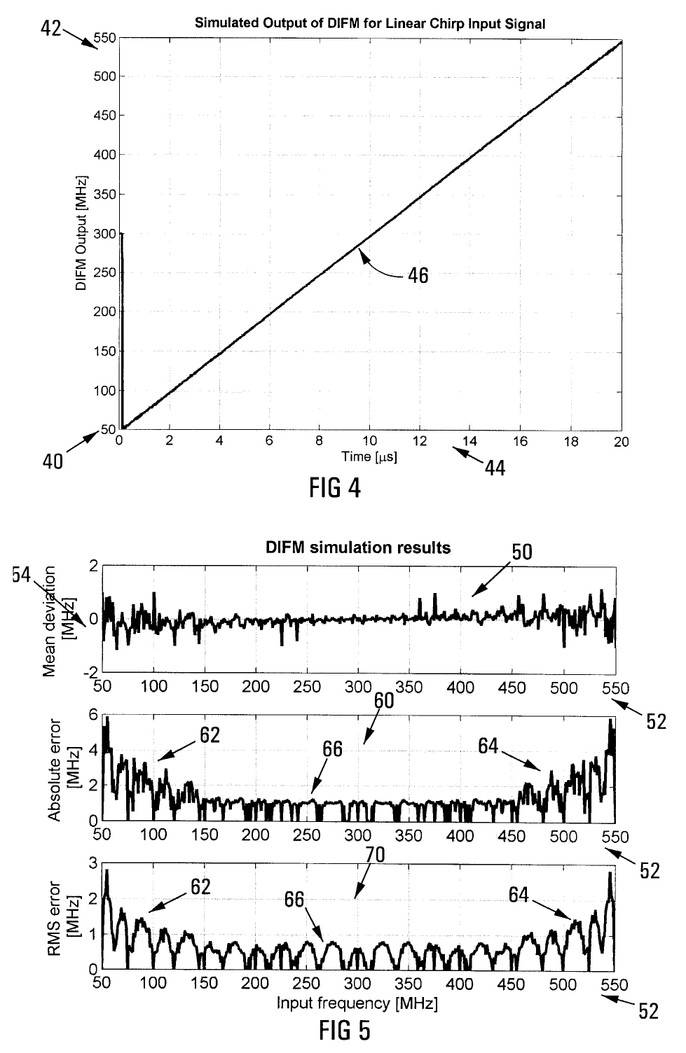

FIG. 4 shows a plotted simulation result, on a graph, for an instantaneous frequency measurement method in accordance with the invention, with a continuous wave (CW) linear chirp signal input;

FIG. 5 shows instantaneous frequency measurement accuracy simulation results for a continuous wave (CW) input; and

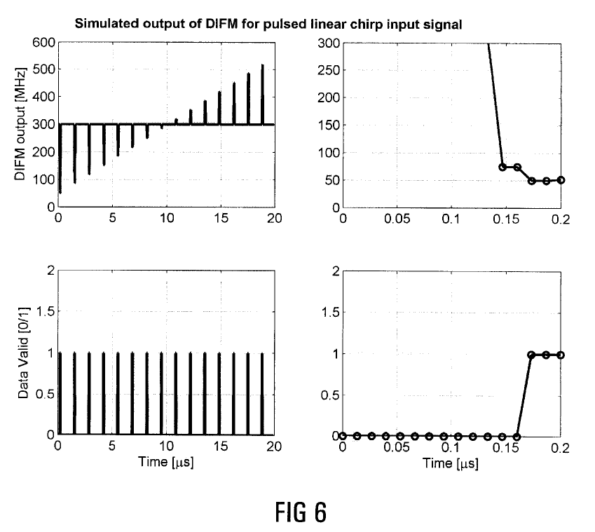

FIG. 6 shows plotted simulation results for an instantaneous frequency measurement method in accordance with the invention, with a pulsed linear chirp signal input.

Referring to FIG. 1 of the drawings, an apparatus in accordance with the invention and generally referred to by reference numeral 8, comprises a 10-bit analog to digital converter (ADC) 10 sampling an input signal 12 at a sampling rate of 1.2 gigasamples per second (GSPS); and a field programmable gate array (FPGA) 16, comprising an input/output port 16.1, in electronic communication with de-multiplexers 14 via dual-port random access memory (DPRAM) 18.

It will be appreciated that four multiplexers 20 and a digital to analog converter (DAC) 21 can be connected in series to the FPGA 16 and to the DPRAM 18, if a time-delayed replica of the digitised waveform of the signal 12 has to be synthesized.

It will be noted that the term input signal denotes any signal sampled by the ADC 10.

Referring to FIG. 2 of the drawings, a high level block diagram of a preferred embodiment of the implementation of the instantaneous frequency measurement technique on the FPGA 16 is shown.

Multiplier-filter elements 22 are connected to FIR filter coefficients 22.4 and to an input bus 23 via input one-cycle delay units 24 and input-cast units 25. Outputs of the multiplier-filter elements 22 are added together by way of an adder 26. It will be understood by those skilled in the art that the multiplier-filter elements 22 together with the FIR filter coefficients 22.4, the input one-cycle delay units 24, the input-cast units 25, and the adder 26 realise the digital mixer and digital filter in accordance with the invention. The output from adder 26 is connected to both a frequency de-multiplexer 28 and an amplitude de-multiplexer 30, both directly and via a one-cycle delay unit 29. An output from the frequency de-multiplexer 28 is connected to an output multiplier 32 via two output one-cycle delay units 28.1 and 28.2. An output from the amplitude de-multiplexer 30 is connected to the output multiplier 32 via an inverse amplitude look-up table 30.1. An output 32.1 from the output multiplier 32 is electronically connected to a digital frequency estimator in the form of a frequency look-up table 34. The frequency look-up table 34 facilitates an inverse cosine estimator. A flip-flop 36 is connected to both the frequency de-multiplexer 28 and the amplitude de-multiplexer 30. It will be noted that the FPGA 16 has an operating speed of 75 MHz.

Referring to FIG. 3 of the drawings, each multiplier-filter element 22 comprises two multiplier-filter multiplexers 22.1 selectively feeding inputs received from input bus 23 (via input one-cycle delay units 24 and input-cast units 25) to a parallel processing multiplier 22.2; and a FIR filter multiplier 22.3 facilitating part of a FIR filter function by multiplying the output from the parallel processing multiplier 22.2 by a FIR filter coefficient 22.4. It will be noted that the FIR filter coefficients 22.4 are selected based on a user's specific requirements.

In use, referring to FIGS. 1, 2 and 3, an input signal 12 i.e. y(t)=A₀ cos(2πf₀t), is sampled and quantised by the ADC 10 yielding:

$$\begin{matrix}{y}_{q} ( n ) = Q [ y ( nt ) ] , T = {f}_{s}^{- 1} \\ = Q [ {A}_{0} cos ( 2 π \frac{{f}_{0}}{{f}_{s}} n ) ] \\ = Q [ {A}_{0} cos ( 2 π {F}_{0} n ) ] , {F}_{0} = \frac{{f}_{0}}{{f}_{s}} \\ = ⌊ \frac{2 {A}_{0}}{D} {2}^{N - 1} cos ( 2 π {F}_{0} n ) + 0.5 ⌋ \\ = \frac{{A}_{0}}{D} {2}^{N} cos ( 2 π {F}_{0} n ) + {ɛ}_{q} ( n ) ,\end{matrix}$$

where T is the ADC 10 sampling period (fₛ⁻¹); D is the ADC 10 peak-to-peak voltage dynamic range; N is the number of bits of the ADC 10, which is ten in this embodiment; A₀ is the amplitude of the input signal 12; F₀ is the normalised input frequency; and ε_{q}(n) is the error due to quantisation of the input signal 12.

In this particular embodiment, with the 10-bit ADC 10 having a sampling rate of 1.2 GSPS, it is necessary to de-multiplex the sampled signal into a databus 14.1 comprising 16 samples i.e. y_{q}(n), y_{q}(n−1), . . . , y_{q}(n−15), before inputting this data to the DPRAM 18 as the sampling rate for this particular ADC 10 exceeds the sampling rate which the DPRAM 18 can handle. The databus 14.1 therefore has a width of 160 bits and a data rate of 75 MHz.

It will be appreciated that the data in the input bus 23 of the FPGA 16 is the data received by the input/output port 16.1 of the FPGA 16 from the databus 14.1 of the de-multiplexers 14 via the DPRAM 18.

In one FPGA 16 clock cycle, the sixteen input samples y_{q}(n), y_{q}(n−1), y_{q}(n−15), are instantaneously available at the FPGA 16 input/output port 16.1 from the de-multiplexers 14 via the DPRAM 18.

In this embodiment, multipliers in the FPGA 16 are 9-bit by 9-bit multipliers. The ADC 10, however, produces 10-bit unsigned values. It is therefore necessary to convert these 10-bit unsigned values to 9-bit signed values so as to conserve resources of the FPGA 16, as it would require at least two 9-bit by 9-bit multipliers to multiply the 10-bit values from the ADC 10. The conversion of the 10-bit values to 9-bit values is realised by way of the input-cast units 25.

It will be noted that with the apparatus 8, as described above, a FIR filter with an order of up to fourteen can be instantiated; however this filter order is insufficient with regards to the cut-off frequency and stop-band rejection requirements for instantaneous frequency measurement.

Therefore to increase the filter order, the FPGA input bus 23 is combined with a one cycle delayed replica of the same bus using input delay units 24.2. In this preferred embodiment a 24^{th} order, Chebychev-windowed, low-pass FIR filter, with a cut-off frequency of 100 MHz (2×50 MHz) and side-lobe suppression exceeding 46 dB, is instantiated. If a higher order filter is needed, the input bus 23 of the FPGA 16 can be broadened further, bearing in mind that this will result in higher hardware resource usage due to increased fan-out.

In order to realise the 24^{th} order FIR filter, as described above, 26 consecutive input samples are needed at the input to 25 multiplier-filter elements 22. It is therefore only required that ten input samples of the input bus 23 be delayed by ten input one-cycle delay units 24.2 to provide the 26 input samples (16 input samples+ten one-cycle delayed samples=26 input samples) i.e. y_{q}(n), y_{q}(n−1), . . . , y_{q}(n−25). A combined bus 23.1, comprising the 26 input samples, y_{q}(n), y_{q}(n−1), . . . , y_{q}(n−25), is then inputted to the 25 multiplier-filter elements 22.

The parallel processing multipliers 22.2 of the multiplier-filter elements 22 generate a mixed signal, yₘᵢₓ(n), yₘᵢₓ(n−1), . . . , yₘᵢₓ(n−24), by multiplying each sample of the sampled input signal, y_{q}(n), y_{q}(n−1), . . . , y_{q}(n−24), by a sample delayed replica thereof, as shown below:

$$\begin{matrix}{y}_{mix} ( n ) = {y}_{q} ( n ) {y}_{q} ( n - 1 ) \\ = \frac{{A}_{0}^{2}}{{D}^{2}} {2}^{2 N - 1} [ cos ( 2 π {F}_{0} ) + cos ( 4 π {F}_{0} n - 2 π {F}_{0} ) ] + \\ \frac{{A}_{0}}{D} {2}^{N} \{ cos ( 2 π {F}_{0} n ) {ɛ}_{q} ( n - 1 ) + cos [ 2 π {F}_{0} ( n - 1 ) ] {ɛ}_{q} ( n ) \} + \\ {ɛ}_{q} ( n ) {ɛ}_{q} ( n - 1 ) .\end{matrix}$$

Each sample of the resultant mixed signal is used as an input to a FIR filter which in its simplest form sums a series of weighted samples of the mixed signal to produce:

$$\begin{matrix}{y}_{filt} ( n ) = {\sum }_{k = 0}^{N} {c}_{k} {y}_{mix} ( n - k ) , \\ = \frac{{A}_{0}^{2}}{{D}^{2}} {2}^{2 N - 1} [ \begin{matrix}\vert {H}_{LPF} ( 0 ) \vert cos ( 2 π {F}_{0} ) + \\ \vert {H}_{LPF} ( {F}_{0}^{′} ) \vert cos ( 2 π {F}_{0}^{′} n - 2 π {F}_{0} + {∠H}_{LPF} ( {F}_{0}^{′} ) )\end{matrix} ] \\ + {ɛ}_{q}^{′} ( n ) ,\end{matrix}$$

where cₖ are FIR filter coefficients 22.4; |H_{LPF}(0)| is the magnitude response of the FIR filter at DC (0 Hz); |H_{LPF}(F′₀)| is the magnitude response of the FIR filter at F′₀; ∠H_{LPF}(F′₀) is the phase response of the FIR filter at F′₀; and ε′_{q}(n) is a derived error due to quantisation and

F′₀=2F₀,f₀≦fₛ/4;

F′₀=1−2F₀,f_{0>f}ₛ/4.

As indicated above, each multiplier-filter element 22 facilitates part of the FIR filter by multiplying each mixed sample of the mixed signal, by a FIR filter coefficient 22.4 by way of the FIR filter multiplier 22.3 i.e. cₖ·yₘᵢₓ(n−k). The output from each multiplier-filter element 22 is subsequently added together by way of an adder 26 resulting in a FIR filter output, at 26.1, i.e. y_{filt}(n) as described in the above equation.

In one embodiment of the invention, the filter output, 26.1, is used directly as an input to an inverse cosine estimator, in the form of a frequency look-up table 34, which outputs an estimate of the radian normalised frequency of the input signal 12, or an estimate that is directly related thereto, based on its received input viz. y_{filt}(n). It will be noted that this estimation of the input frequency is dependent on the amplitude, Aₒ, of the input signal 12 being known a priori.

If the amplitude, Aₒ, of the input signal 12 is available timeously as a digital word, the FIR filter output, y_{filt}(n), is however preferably digitally divided by the square of the amplitude Aₒ i.e.

$$\begin{matrix}{y}_{div} ( n ) = \frac{{y}_{filt} ( n )}{{A}^{2} ( n )} \\ = \frac{{y}_{filt} ( n )}{{[ {A}_{0} + {ɛ}_{a} ( n ) ]}^{2}} \\ \approx \frac{{y}_{filt} ( n )}{{A}_{0}^{2}} , {A}_{0} >> {ɛ}_{a} ( n ) \\ \approx \frac{{2}^{2 N - 1}}{{D}^{2}} [ \begin{matrix}\vert {H}_{LPF} ( 0 ) \vert cos ( 2 π {F}_{0} ) + \\ \vert {H}_{LPF} ( {F}_{0}^{′} ) \vert cos ( 2 π {F}_{0}^{′} n - 2 π {F}_{0} + {∠H}_{LPF} ( {F}_{0}^{′} ) )\end{matrix} ] + \\ \frac{{ɛ}_{q}^{′} ( n )}{{A}_{0}^{2}} ,\end{matrix}$$

where A(n) is the digital estimation of the instantaneous amplitude of the input signal 12. The quotient, as shown above, is then used as the input to the frequency look-up table 34 to output the estimate of the radian normalised frequency, or an estimate that is directly related thereto, of the input signal 12. By digitally dividing the FIR filter output y_{filt}(n) by the square of A(n) and using the quotient as an input to the frequency look-up table 34, the instantaneous frequency estimation outputted from the frequency look-up table 34 would not be dependent on the amplitude of the input signal 12.

In the preferred embodiment, as above described, the digital estimation of the square of the instantaneous amplitude, A²(n), of the input signal 12 is obtained by using the same apparatus 8, as described above, on a timesharing basis (time-division multiplexing) such that on one clock cycle (m^{th} clock cycle) the FPGA 16 of apparatus 8 calculates y_{filt}(n), and on the next clock cycle ((m+1)^{th} clock cycle) the FPGA 16 obtains the digital estimation of the square of the instantaneous amplitude, A²(n), of the input signal 12.

It will be appreciated that in order to obtain an accurate digital estimation of the square of the instantaneous amplitude, A²(n), the same input samples, in the input bus 23, which is signal processed to yield y_{filt}(n), must be used to obtain the digital estimation of the square of the instantaneous amplitude, A²(n). This is achieved by making use of fifteen additional input one-cycle delay units 24.1 (six units in addition to the ten already mentioned) and 24.2 (nine units). Thus the combined bus 23.1 comprises forty-one samples y_{q}(n), y_{q}(n−1), . . . , y_{q}(n−40).

In order to facilitate the timesharing (time-division multiplexing) of the FPGA 16, the flip-flop 36 generates a toggle signal 36.1 which toggles between ‘0’ and ‘1’ on every FPGA clock cycle. This toggle signal 36.1 is used to select which signal is outputted by the multiplier-filter multiplexers 22.1. On the m^{th} FPGA clock cycle, y_{filt}(n) as described above, is calculated from the input samples y_{q}(n), y_{q}(n−1), . . . , y_{q}(n−25), with m=2k, k=0, 1, 2, . . . and n=16m. On the (m+1)^{th} (alternate FPGA clock cycle), A²(n), is calculated from the input samples y_{q}(n−16), y_{q}(n−17), . . . , y_{q}(n−40).

This toggle signal 36.1 is also passed to the amplitude and frequency de-multiplexers 30 and 28 respectively, to allow these units to time-domain de-multiplex the output 26.1 of the adder 26. This process is assisted by the one-cycle delay unit 29 and by inverting the polarity of the amplitude de-multiplexer select line. The amplitude de-multiplexer 30 will output the estimate of the square of the amplitude, at 30.2, which will be valid for two clock cycles. The frequency de-multiplexer 28 will output y_{filt}(n), at 28.3, which will also be valid for two clock cycles.

To estimate the square of the instantaneous amplitude, A²(n), multiplier-filter multiplexers 22.1 output a sample and a replica thereof (without a sample shift) to the parallel processing multiplier 22.2 on each alternate FPGA clock cycle (m+1) to produce a square of the input sample i.e. y′ₘᵢₙ(n)=y_{q}(n−16)y_{q}(n−16−0)=y_{q}(n−16)y_{q}(n−16)=y_{q}²(n−16).

The square of the sampled input signal, y_{q}²(n−16), is also inputted to the FIR filter multiplier 22.3 where each mixed sample y′ₘᵢₓ(n), y′ₘᵢₓ(n−1) . . . y′ₘᵢₓ(n−24), is multiplied with an FIR filter coefficient 22.4. These products are also added together by adder 26, as above described, to yield the FIR filter output y′_{filt}(n), also at 26.1 i.e.

$${y}_{filt}^{′} ( n ) = \frac{{A}_{0}^{2}}{{D}^{2}} {2}^{2 N - 1} [ \begin{matrix}\vert {H}_{LPF} ( 0 ) \vert + \\ \vert {H}_{LPF} ( {F}_{0}^{′} ) \vert cos ( \begin{matrix}2 π {F}_{0}^{′} n + \\ {∠H}_{LPF} ( {F}_{0}^{′} )\end{matrix} )\end{matrix} ] + {ɛ}_{q}^{″} ( n ) .$$

This filter output, y′_{filt}(n), is used as the digital estimation of the square of the instantaneous amplitude, A²(n), of the input signal 12.

It will be appreciated that at the filter output 26.1 there is the FIR filter output y_{filt}(n), on the m^{th} clock cycle, and the digital estimation of the square of the instantaneous amplitude, A²(n), on the (m+1)^{th} clock cycle. It is therefore possible to digitally divide y_{filt}(n) by A²(n), to provide an amplitude independent input to the frequency look-up table 34, as described above.

To facilitate the digital division, the output 26.1 from the adder 26 is passed to the amplitude de-multiplexer 30 and to the frequency de-multiplexer 28 directly, and also via an output one-cycle delay unit 29. A²(n) is subsequently made available at the output 30.2 of the amplitude de-multiplexer 30 and y_{filt}(n) is made available at the output 28.3 of the frequency de-multiplexer 28. It will be noted that the amplitude de-multiplexer 30 and the frequency de-multiplexer 28 time-domain de-multiplex the output 26.1 from the adder 26 such that the signals are valid for two clock cycles with a delay mismatch of one FPGA clock cycle.

In this particular embodiment, A²(n) is passed to an inverse amplitude look-up table 30.1 which outputs an inverse of A²(n) to facilitate the digital division. Since there is a one-cycle mismatch between obtaining A²(n) and obtaining y_{filt}(n); and another one-cycle mismatch in obtaining the inverse of A²(n) from the amplitude look-up table 30.1, two output one-cycle delay units 28.1 and 28.2 are used to remove the two cycle mismatch between the inverse of A²(n) and y_{filt}(n) such that they are present on the same FPGA clock cycle. It will be noted that the output one-cycle delay unit 29 is provided to assist in bringing A²(n) and y_{filt}(n) on the same FPGA clock cycle. The inverse of A²(n) (denominator) and y_{filt}(n) (numerator) are thereafter multiplied together by way of output multiplier 32 to yield:

$${y}_{div} ( n ) = \frac{\frac{{A}_{0}^{2}}{{D}^{2}} {2}^{2 N - 1} [ \begin{matrix}\vert {H}_{LPF} ( 0 ) \vert cos ( 2 π {F}_{0} ) + \\ \vert {H}_{LPF} ( {F}_{0}^{′} ) \vert cos ( \begin{matrix}2 π {F}_{0}^{′} n - \\ \begin{matrix}2 π {F}_{0} + \\ {∠H}_{LPF} ( {F}_{0}^{′} )\end{matrix}\end{matrix} )\end{matrix} ] + {ɛ}_{q}^{′} ( n )}{\frac{{A}_{0}^{2}}{{D}^{2}} {2}^{2 N - 1} [ \begin{matrix}\vert {H}_{LPF} ( 0 ) \vert + \\ \vert {H}_{LPF} ( {F}_{0}^{′} ) \vert cos ( \begin{matrix}2 π {F}_{0}^{′} n + \\ {∠H}_{LPF} ( {F}_{0}^{′} )\end{matrix} )\end{matrix} ] + {ɛ}_{q}^{″} ( n )} \approx cos ( 2 π {F}_{0} ) + \frac{\vert {H}_{LPF} ( {F}_{0}^{′} ) \vert}{\vert {H}_{LPF} ( 0 ) \vert} cos ( 2 π {F}_{0}^{′} n - 2 π {F}_{0} + {∠H}_{LPF} ( {F}_{0}^{′} ) ) + {ɛ}_{q}^{′′′} ( n ) \approx cos ( 2 π {F}_{0} ) , \frac{\vert {H}_{LPF} ( {F}_{0}^{′} ) \vert}{\vert {H}_{LPF} ( 0 ) \vert} << cos(2 π {F}_{0} ) and {ɛ}_{q}^{′′′} ( n ) << cos(2 π {F}_{0} ) .$$

The quotient i.e. output 32.1 of the output multiplier 32, is then used as an input to the inverse cosine estimator, which in this embodiment is the frequency look-up table 34 which outputs, at 38, an estimate of the radian normalised frequency of the input signal 12, or an estimate that is directly related thereto.

Referring to FIG. 4 of the drawings, a simulation of the digital instantaneous frequency measurement (DIFM) technique, as above described, for a continuous wave (CW) linear chirp input signal was run using a computerised mathematical toolkit. The CW linear chirp input signal was set with a start frequency of 50 MHz, 40, and a stop frequency of 550 MHz, 42, and a sweep period of 20 μs, 44. From the line graph 46 it is clear that the output follows the input in a linearly fashion.

For brevity, DIFM will denote the instantaneous frequency measurement as above described.

Referring to FIG. 5 of the drawings, an accuracy simulation was also performed to determine the accuracy of the DIFM for CW input signals. The input for this simulation was a fixed frequency, fixed amplitude CW signal with an integration period of 20 μs. Over the integration period, the deviation 50 between the mean output frequency and the input frequency was measured; and absolute as well as root-mean-squared (RMS) frequency errors, 60 and 70 respectively, were calculated. This simulation was repeated across a frequency range 52 of interest, i.e. 50 MHz to 550 MHz.

From FIG. 5 it can be observed that the mean output frequency 50 deviated from the input frequency by less than ±2 MHz, 54, across the frequency range of interest, 52. The absolute error 60, as well as the RMS error 70 has a distinctive frequency response, being worst at the extreme (low 62 and high 64) frequency and best close to the centre frequency, 66. The absolute error 60 is less than or equal to 6 MHz at the extreme frequencies, 62 and 64, and less than 2 MHz in a greater than 300 MHz frequency range about the centre frequency, 66. Correspondingly, the RMS error 70 is less than 3 MHz at the extreme frequencies, 62 and 64, and less than 1 MHz in a greater than 300 MHz frequency range about the centre frequency, 66.

The abovementioned results are for an input bit width of nine bits, multiplier truncation to nine bits, 9-bit FIR filter coefficients and a 12-bit lookup table address width. It will be noted that dedicated multipliers found in state-of-the-art FPGA's are made up of 9-bit by 9-bit multiplier elements and it is therefore advisable to configure multipliers with bit widths equal to an integer multiple of nine. Simulations show that 10-bit multiplication, truncation and filtering yield better results than those depicted in FIG. 5, but are highly inefficient, since two multiplier units are required for each 10-bit multiplier. It is important to note however, that performance can be improved at the expense of FPGA resources.

Referring to FIG. 6 of the drawings, the simulation results of the response of the DIFM to pulsed input signals are plotted in FIG. 6. The input is a pulse train with a PRI of 750 kHz and a pulse width of 66.666 ns, while the centre frequency is swept from 50 MHz to 550 MHz in 20 μs.

From FIG. 6 it can be derived that the DIFM also has an excellent pulse response. The output settles in three FPGA clock cycles with a latency of 173.333 ns or 13 FPGA clock cycles.

In another embodiment of the invention, the apparatus as above described is in the form of existing circuitry on a DDM (digital DRFM (digital radio frequency memory) module). In this embodiment, it will be appreciated that the FPGA will therefore have to be programmed to effect the instantaneous frequency measurement as described above.

The applicant believes that the instantaneous frequency measurement method as implemented on the apparatus, as above described, improves performance in terms of accuracy and latency as compared to conventional means of measuring instantaneous frequency of continuous waves, swept frequency waves and pulsed waves.

1-22. (canceled)

23. A method of instantaneously determining or estimating the frequency of an input signal, the method including:
mixing a digitally sampled and quantized input signal by a time shifted replica of the input signal, where the time shift equals an integer multiple of a sampling period of the input signal, thereby producing a mixed signal;
filtering the mixed signal with a low-pass filter producing a filtered signal;
obtaining an estimate of the square of the amplitude of the input signal;
dividing the filtered signal with the estimate of the square of the amplitude of the input signal thereby producing a quotient signal; and
using the quotient signal to obtain an estimate of the frequency of the input signal.

24. The method of claim 23, which includes the prior steps of:
sampling and quantising an input signal thereby to generate a digitally sampled and quantised input signal; and
shifting the digitally sampled and quantised input signal by an integer multiple of the sampling period of the input signal thereby to generate a time shifted replica of the input signal.

25. The method of claim 23, in which the time shift equals the sampling period.

26. The method of claim 23, in which using the quotient signal to obtain an estimate of the frequency of the input signal includes using the quotient signal as a digital input to a digital frequency estimator, the digital frequency estimator being operable digitally to output an estimated frequency of the input signal based on the received quotient signal.

27. The method of claim 23, in which the estimate of the square of the amplitude of the input signal is obtained in the form of a digital word, the filtered signal thus being digitally divided by the estimate of the square of the amplitude of the input signal providing the quotient signal.

28. The method of 23, in which obtaining the estimate of the square of the amplitude of the input signal includes:
mixing the sampled input signal with a duplicate of the sampled input signal to provide the square of the sampled input signal; and
filtering the square of the sampled input signal with a low-pass filter producing a filtered square of the sampled input signal, which is used as the estimate of the square of the amplitude of the input signal.

29. The method of claim 28, in which the low-pass filter is the same low-pass filter used to filter the mixed signal.

30. The method claim 29, in which the low-pass filter filters out second and any higher order harmonics of the square of the sampled input signal, so that the filtered square of the sampled input signal is a constant.

31. The method of claim 28, which is implemented on a programmable processing unit and which includes timesharing the processing unit such that on one clock cycle of the processing unit the filtered square of the sampled input signal is obtained and on an alternate clock cycle of the processing unit the filtered signal is obtained.

32. The method of claim 23, in obtaining the estimate of the square of the amplitude of the input signal includes:
mixing the sampled input signal with a duplicate of the sampled input signal to provide the square of the sampled input signal; and
filtering the square of the sampled input signal with a low-pass filter producing a filtered square of the sampled input signal, which is used as the estimate of the square of the amplitude of the input signal, the method being implemented on a programmable processing unit and the method including timesharing the processing unit such that on one clock cycle of the processing unit the filtered square of the sampled input signal is obtained and on an alternate clock cycle of the processing unit the filtered signal is obtained, with the digitally sampled and quantized input signal being de-multiplexed before being fed to the programmable processing unit.

33. An apparatus for measuring the instantaneous frequency of an input signal, the apparatus including:
a digital mixer operable digitally to mix a digitally sampled and quantized input signal by a sample shifted replica of the input signal, where the sample shift is an integer sample shift, thereby producing a mixed signal;
a digital low-pass filter operable to filter the mixed signal thereby producing a filtered signal;
means to obtain an estimate of the square of the amplitude of the input signal;
means digitally to divide the filtered signal with the estimate of the square of the amplitude of the input signal to provide a quotient signal; and
a digital frequency estimator operable to receive the quotient signal and output an estimate of the radian normalized frequency of the input signal or an estimate that is directly related thereto, based on the received quotient signal.

34. The apparatus of claim 33, which includes a programmable processing unit, the programmable processing unit being programmed to include or define the digital mixer, the digital filter, the means to digitally divide and the digital frequency estimator.

35. The apparatus of claim 34, the apparatus including:
a plurality of multiplier-filter elements programmed into the processing unit, the multiplier-filter elements being operable digitally to mix the digitally sampled and quantised input signal by a sample delayed replica thereof, thereby producing the mixed signal, and also operable to multiply the mixed signal by finite impulse response (FIR) filter coefficients, thereby producing multiplier-filter outputs; and
an adder programmed into the processing unit, the adder being operable digitally to add the multiplier-filter outputs together, thereby producing an adder output which is the filtered signal, such that the digital mixer and the digital low-pass filter are implemented by way of the multiplier-filter elements and the adder.

36. The apparatus of claim 34, which includes:
an analog to digital converter (ADC) operable to sample and quantize an input signal thereby to generate a digitally sampled and quantized input signal; and
at least one de-multiplexer operable digitally to receive the sampled and quantized input signal from the ADC and digitally transfer the sampled and quantized input signal to an input bus of the programmable processing unit with a wider bus width and a lower data rate.

37. The apparatus of claim 33, wherein the digital frequency estimator includes an inverse cosine estimator, the inverse cosine estimator including a frequency look-up table operable to receive the quotient signal and output an estimate of the radian normalized frequency of the input signal or an estimate that is directly related thereto, based on the received quotient signal.

38. The apparatus of claim 36, in which each multiplier-filter element of the programmable processing unit includes:
at least two multiplier-filter two-port multiplexers, both electronically connected to receive samples of the input signal from the input bus of the processing unit, the at least two multiplier-filter two-port multiplexers each defining output means operable to output a sample replica and a sample delayed replica of the input signal, or to output two sample replicas of the input signal or two output two samples replicas of the input signal that are delayed by one or more programmable processing unit clock cycles(s);
a parallel processing multiplier operable digitally to multiply together the samples received from the output means of the multiplier-filter multiplexers, thereby to produce a mixed product; and
a finite impulse response (FIR) filter multiplier operable digitally to multiply the mixed product by a FIR filter coefficient, the FIR filter coefficients being low-pass filter coefficients.

39. The apparatus of claim 38, which includes a switch to switch the multiplier-filter multiplexers of the multiplier-filter element to output a sample and a sample delayed replica thereof on an m^{th} clock cycle, and to output two sample replicas or two samples that are delayed by one or more programmable processing unit clock cycle(s) on an (m+1)^{th} (alternate) clock cycle, such that the adder output is the filtered signal (sample delayed) on the m^{th} clock cycle and the adder output is an estimate of the square of the amplitude of the input signal on the (m+1)^{th} clock cycle.

40. The apparatus of claim 34, in which the programmable processing unit is also programmed to include:
at least one amplitude de-multiplexer and a frequency de-multiplexer, both electronically connected to receive the adder output; and
an output multiplier operable to multiply together an input received from the amplitude de-multiplexer via an inverse amplitude look-up table, and also an input received from the frequency de-multiplexer, thereby to produce an output which is used as an input to the frequency look-up table which outputs an amplitude independent estimation of the normalized radian frequency of an input signal or an estimate that is directly related thereto.

41. The apparatus of claim 40, in which the programmable processing unit includes cycle delay units electronically connected between the frequency de-multiplexer and the multiplier, operable to remove any cycle delay mismatch between the filtered signal and the input received from the amplitude de-multiplexer via the inverse amplitude look-up table at the input to the output multiplier.
